(19) United States
(12) Patent Application Publication
(10) Pub. No.: US 2024/0312969 A1
(43) Pub. Date: Sep. 19, 2024

(54) SEMICONDUCTOR DEVICE

(71) Applicant: Renesas Electronics Corporation, Tokyo (JP)

(72) Inventors: Takayuki IGARASHI, Tokyo (JP); Tatsuo KASAOKA, Tokyo (JP); Yasutaka NAKASHIBA, Tokyo (JP)

(21) Appl. No.: 18/588,091

(22) Filed: Feb. 27, 2024

(30) Foreign Application Priority Data
Mar. 15, 2023 (JP) 2023-041305

(51) Int. Cl. H01L 25/16; H01L 23/00

(52) U.S. Cl. CPC H01L 25/162; H01L 24/48; H01L 2224/48195; H01L 2924/1206

(57) ABSTRACT

A semiconductor chip includes a semiconductor substrate and a multilayer wiring layer formed on the semiconductor substrate, and at least one layer of the multilayer wiring layer is formed with a conductive pattern. The conductive pattern is formed so as to continuously surround a lower inductor and an upper inductor in plan view.

### CROSS-REFERENCE TO RELATED APPLICATIONS

The disclosure of Japanese Patent Application No. 2023-041305 filed on Mar. 15, 2023, including the specification, drawings and abstract is incorporated herein by reference in its entirety.

### BACKGROUND

The present disclosure relates to a semiconductor device and, more particularly, to a technique that can be effectively applied to a semiconductor device in which a pair of inductors are inductively coupled to transmit signals between different potentials.

There is a disclosed technique listed below.
[Patent Document 1] Japanese Unexamined Patent Application Publication No. 2011-82212

Patent Document 1 describes a technique capable of increasing the cross-sectional area of a coil without hindering miniaturization in order to reduce the series resistance that occupies most of the parasitic resistance components of the coil configuring the transformer.

### SUMMARY

For example, there is a transformer (digital isolator) that performs non-contact signal transmission using a pair of inductors coupled inductively. According to this transformer, since signal transmission in a non-contact state is possible, it is possible to suppress the electric noise generated in one circuit from adversely affecting the other circuit.

In a semiconductor device realizing a transformer, it has been studied to separately form a semiconductor chip in which a pair of inductors are formed and a semiconductor chip in which a transistor configuring an integrated circuit is formed from the viewpoint of enhancing versatility of a semiconductor chip on which a transformer is formed and reducing manufacturing costs.

However, in this case, since the transistor is not formed in the semiconductor chip in which the pair of inductors are formed, there is a possibility that the pattern occupancy ratio becomes low. For example, when the pattern occupancy ratio in the semiconductor chip is low, a warp is likely to occur in the semiconductor wafer, and handling of the semiconductor wafer may become difficult.

The low pattern occupancy ratio means that the area of the conductive film removed by etching is large in the etching of the conductive film for forming the pattern. The large etching area means that etching residues are likely to be generated. Therefore, in a manufacturing step of a semiconductor chip having a low pattern occupancy ratio, foreign matters caused by etching residues are likely to be generated, and there is a possibility that a manufacturing yield is lowered.

For this reason, it is desired to increase the pattern occupancy ratio in a semiconductor chip in which a transistor is not formed, while a pair of inductors is formed.

In this specification, a semiconductor chip in which a transistor is not formed and a pair of inductors is formed is sometimes referred to as a “trans-chip”.

According to one embodiment, a semiconductor device includes a first semiconductor chip in which a transistor is not formed. The first semiconductor chip has a conductive pattern formed in at least one layer of a multilayer wiring layer, and the conductive pattern continuously surrounds a lower inductor and an upper inductor in plan view.

According to one embodiment, the pattern occupancy ratio of the semiconductor chip can be improved.

### BRIEF DESCRIPTION OF THE DRAWINGS

FIG. 1 is a diagram showing a configuration example of a drive control unit that drives a load circuit.

FIG. 2 is an explanatory diagram showing a signal transmission example.

FIG. 3 is a diagram showing a three-chip configuration.

FIG. 4 is a cross-sectional view showing a configuration of a semiconductor device in an embodiment.

FIG. 5A is a plan view showing a first wiring layer of the multilayer wiring layer formed in a “trans-chip”.

FIG. 5B is a plan view showing a second wiring layer disposed over the first wiring layer.

FIG. 5C is a plan view showing each of a third wiring layer disposed over the second wiring layer and a fourth wiring layer disposed over the third wiring layer.

FIG. 5D is a plan view showing a fifth wiring layer disposed over the fourth wiring layer.

FIG. 6 is a cross-sectional view along A-A line of FIG. 5.

FIG. 7 is a schematic diagram showing an example of a plug.

### DETAILED DESCRIPTION

In all the drawings for explaining the embodiments, the same members are denoted by the same reference numerals in principle, and repetitive descriptions thereof are omitted. Note that even plan view may be hatched for the sake of clarity.

### Circuit Configuration

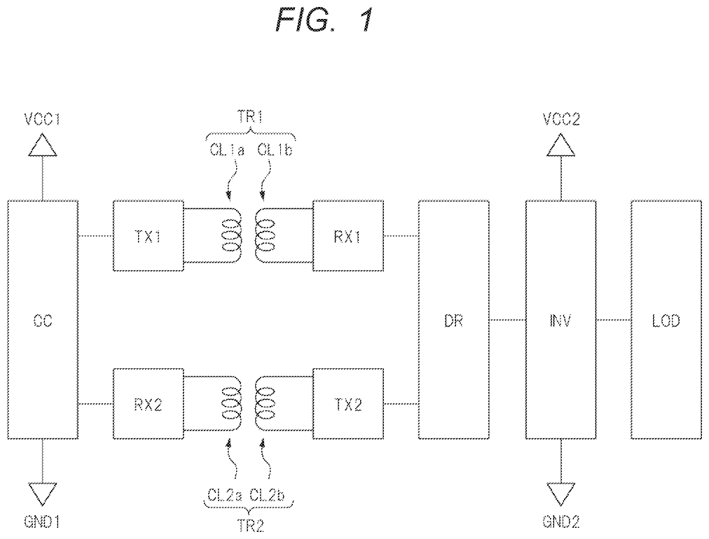

FIG. 1 is a diagram showing a configuration example of a drive control unit that drives the load circuit such as a motor.

As shown in FIG. 1, the drive control unit includes a control circuit CC, a transformer TR1, a transformer TR2, a drive circuit DR, and an inverter INV, and is electrically connected to a load circuit LOD.

The control signal outputted from the control circuit CC is transmitted to the drive circuit DR via a transmitting circuit TX1 and a receiving circuit RX1. On the other hand, a signal outputted from the drive circuit DR is transmitted to the control circuit CC via a transmitting circuit TX2 and a receiving circuit RX2.

The control circuit CC has a function of controlling the drive circuit DR. The drive circuit DR operates the inverter INV that controls the load circuit LOD based on a control signal from the control circuit CC.

The control circuit CC is supplied with a power supply potential VCC1, and the control circuit CC is grounded by a ground potential GND1. On the other hand, the inverter INV is supplied with a power supply potential VCC2, and the inverter INV is grounded by a ground potential GND2. In this case, for example, the power supply potential VCC1 supplied to the control circuit CC is smaller than the power supply potential VCC2 supplied to the inverter INV.

The transformer TR1 formed of a coil CL1a and a coil CL1b inductively (magnetically) coupled to each other is interposed between the transmitting circuit TX1 and the receiving circuit RX1. Thus, a signal can be transmitted from the transmitting circuit TX1 to the receiving circuit RX1 via the transformer TR1. Consequently, the drive circuit DR can receive the control signal outputted from the control circuit CC via the transformer TR1.

As described above, the transformer TR1 electrically isolated using the inductive coupling enables transmitting the control signal from the control circuit CC to the drive circuit DR while suppressing the transfer of the electric noise from the control circuit CC to the drive circuit DR. Therefore, a malfunction of the drive circuit DR caused by the superimposition of the electric noise on the control signal can be suppresses. Thus, the operation reliability of the semiconductor device can be improved.

The coil CL1a and the coil CL1b configuring the transformer TR1 each function as an inductor. The transformer TR1 functions as a magnetic coupling device including the coil CL1a and the coil CL1b inductively coupled to each other.

Similarly, the transformer TR2 formed of a coil CL2b and a coil CL2a inductively coupled to each other is interposed between the transmitting circuit TX2 and the receiving circuit RX2. Thus, a signal can be transmitted from the transmitting circuit TX2 to the receiving circuit RX2 via the transformer TR2. Consequently, the control circuit CC can receive the signal outputted from the drive circuit DR via the transformer TR2.

As described above, the transformer TR2 electrically isolated using the inductive coupling enables transmitting the signal from the drive circuit DR to the control circuit CC while suppressing the transfer of the electric noise from the drive circuit DR to the control circuit CC. Therefore, a malfunction of the control circuit CC caused by the superimposition of the electric noise on the signal can be suppresses. Thus, the operation reliability of the semiconductor device can be improved.

The transformer TR1 is configured by the coil CL1a and the coil CL1b, and the coil CL1a and the coil CL1b are not connected by conductors but are magnetically coupled. Therefore, when a current flows in the coil CL1a, an induced electromotive force is generated in the coil CL1b in accordance with a change in the current, and an induced current flows. In this case, the coil CL1a is a primary coil, and the coil CL1b is a secondary coil. As described above, the transformer TR1 utilizes the electromagnetic induction phenomenon occurring between the coil CL1a and the coil CL1b. That is, as a result of transmitting a signal from the transmitting circuit TX1 to the coil CL1a of the transformer TR1 to flow a current, the receiving circuit RX1 detects an induced current generated in the coil CL1b of the transformer TR1, so that the receiving circuit RX1 can receive a signal corresponding to the control signal outputted from the transmitting circuit TX1.

Similarly, the transformer TR2 is configured by the coil CL2a and the coil CL2b, and the coil CL2a and the coil CL2b are not connected by conductors but are magnetically coupled. Therefore, when a current flows in the coil CL2b, an induced electromotive force is generated in the coil CL2a in accordance with a change in the current, and an induced current flows. As described above, as a result of transmitting a signal from the transmitting circuit TX2 to the coil CL2b of the transformer TR2 to flow a current, the receiving circuit RX2 detects an induced current generated in the coil CL2a of the transformer TR2, so that the receiving circuit RX2 can receive a signal corresponding to the control signal outputted from the transmitting circuit TX2.

The transmission and reception of signals between the control circuit CC and the drive circuit DR are performed in a path from the transmitting circuit TX1 to the receiving circuit RX1 via the transformer TR1 and a path from the transmitting circuit TX2 to the receiving circuit RX2 via the transformer TR2. That is, when the receiving circuit RX1 receives a signal transmitted by the transmitting circuit TX1 and the receiving circuit RX2 receives a signal transmitted by the transmitting circuit TX2, it is possible to transmit and receive a signal between the control circuit CC and the drive circuit DR. As described above, the transformer TR1 is interposed in the signal transmission from the transmitting circuit TX1 to the receiving circuit RX1, and the transformer TR2 is interposed in the signal transmission from the transmitting circuit TX2 to the receiving circuit RX2. Thus, the drive circuit DR can drive the inverter INV operating the load circuit LOD in accordance with the control signal transmitted from the control circuit CC.

The reference potential is different between the control circuit CC and the drive circuit DR. That is, as shown in FIG. 1, in the control circuit CC, the reference potential is fixed to the ground potential GND1, while the drive circuit DR is electrically connected to the inverter INV.

The inverter INV includes, for example, a high-side IGBT (Insulated Gate Bipolar Transistor) and a low-side IGBT. Then, the drive circuit DR performs on/off control of the high-side IGBT and on/off control of the low-side IGBT, thereby realizing control of the load circuit LOD by the inverter INV.

Specifically, the drive circuit DR performs the on/off control of the high-side IGBT by controlling the potential applied to the gate electrode of the high-side IGBT. Similarly, the drive circuit DR performs the on/off control of the low-side IGBT by controlling the potential applied to the gate electrode of the low-side IGBT.

Here, for example, the on-control of the low-side IGBT is realized by applying “emitter potential (0 V)+threshold voltage (15 V)” to the gate electrode with reference to the emitter potential (0V) of the low-side IGBT connected to the ground potential GND2.

On the other hand, for example, the off-control of the low-side IGBT is realized by applying an “emitter potential (0 V)” to the gate electrode with reference to the emitter potential (0 V) of the low-side IGBT connected to the ground potential GND2.

Therefore, the on/off control of the low-side IGBT is performed according to whether or not applying the threshold voltage (15 V) to the gate electrode with 0 V as a reference potential.

On the other hand, for example, the on-control of the high-side IGBT is also performed by whether or not “reference potential+threshold voltage (15V)” is applied to the gate electrode with the emitter potential of the high-side IGBT as a reference potential.

However, the emitter potential of the high-side IGBT is not fixed to the ground potential GND2 as is the emitter potential of the low-side IGBT. That is, the high-side IGBT and the low-side IGBT are connected in series between the power supply potential VCC2 and the ground potential GND2 in the inverter INV. In the inverter INV, when the high-side IGBT is turned on under the control of the drive circuit DR, the low-side IGBT is turned off, while when the high-side IGBT is turned off, the low-side IGBT is turned on.

Therefore, when the high-side IGBT is set to off-state, since the low-side IGBT is set to on-state, the emitter potential of the high-side IGBT becomes the ground potential GND2 due to the low-side IGBT set to on-state.

On the other hand, when the high-side IGBT is set to on-state, since the low-side IGBT is set to off-state, the emitter potential of the high-side IGBT becomes an IGBT bus voltage.

As described above, the emitter potential of the high-side IGBT varies depending on whether the high-side IGBT is in the on-state or the off-state. That is, the emitter potential of the high-side IGBT varies from the ground potential GND2 (0 V) to the power supply potential VCC2 (for example, 800 V). Therefore, in order to set the high-side IGBT to on-state, the “IGBT bus voltage (800 V)+threshold voltage (15 V)” needs to be applied to the gate electrode with the emitter potential of the high-side IGBT as a reference potential.

Therefore, the emitter potential of the high-side IGBT needs to detect by the drive circuit DR that performs the on/off control of the high-side IGBT. Therefore, the drive circuit DR is configured to receive the emitter potential of the high-side IGBT. Consequently, the drive circuit DR receives the reference potential of 800 V, and the drive circuit DR applies the threshold voltage of 15 V to the gate electrode of the high-side IGBT with respect to the reference potential of 800 V, thereby turning on the high-side IGBT. Therefore, a high potential of the order of 800 V is applied to the drive circuit DR.

As described above, the drive control unit includes the control circuit CC that handles the low potential (several tens of volts) and the drive circuit DR that handles the high potential (several hundreds of volts). Therefore, it is required to transmit a signal between the control circuit CC and the drive circuit DR between the different potential circuits. In this regard, the signal transmission between the control circuit CC and the drive circuit DR is performed via the transformer TR1 and the transformer TR2, so that the signal can be transmitted between different potential circuits.

As described above, a large potential difference may be generated between the primary coil and the secondary coil in the transformer TR1 and the transformer TR2. Conversely, since a large potential difference may occur, a primary coil and a secondary coil that are magnetically coupled to each other without being connected by a conductor are used for signal transmission. Therefore, from the viewpoint of improving the operation reliability of the semiconductor device, it is necessary to make the breakdown voltage between the coil CL1a and the coil CL1b in the transformer TR1 as high as possible. Similarly, from the viewpoint of improving the operation reliability of the semiconductor device, it is necessary that the breakdown voltage between the coil CL2b and the coil CL2a is as high as possible in the transformer TR2.

### Signal Transmission Example

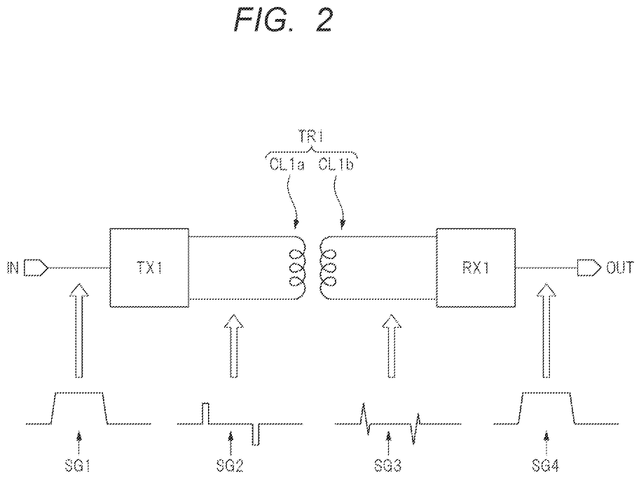

FIG. 2 is an explanatory diagram showing the signal transmission example.

In FIG. 2, the transmitting circuit TX1 extracts an edge part of a signal SG1 of the square wave inputted to the transmitting circuit TX1, generates a signal SG2 having a constant pulse width, and transmits the signal SG2 to the coil CL1a (primary coil) of the transformer TR1. When a current caused by the signal SG2 flows to the coil CL1a (primary coil), a signal SG3 corresponding to the current flows to the coil CL1b (secondary coil) of the transformer TR1 by the induced electromotive force. The receiving circuit RX1 amplifies the signal SG3 and further modulates into a square wave, and then the receiving circuit RX1 outputs a signal SG4 of the square wave. Thus, the receiving circuit RX1 can output the signal SG4 corresponding to the signal SG1 inputted to the transmitting circuit TX1. In this way, the signal can be transmitted from the transmitting circuit TX1 to the receiving circuit RX1. Similarly, the signal transmission can be transmitted from the transmitting circuit TX2 to the receiving circuit RX2.

### Three-Chip Configuration

For example, in the semiconductor device realizing the transformer, from the viewpoint of increasing the versatility of the semiconductor chip in which the transformer is formed and reducing the manufacturing cost, it has been studied to form separately a semiconductor chip in which a pair of inductors is formed and a semiconductor chip in which a transistor configuring the integrated circuit. Specifically, it has been studied to realize the above-described semiconductor device in a three-chip configuration.

Hereinafter, a novel three-chip configuration will be described.

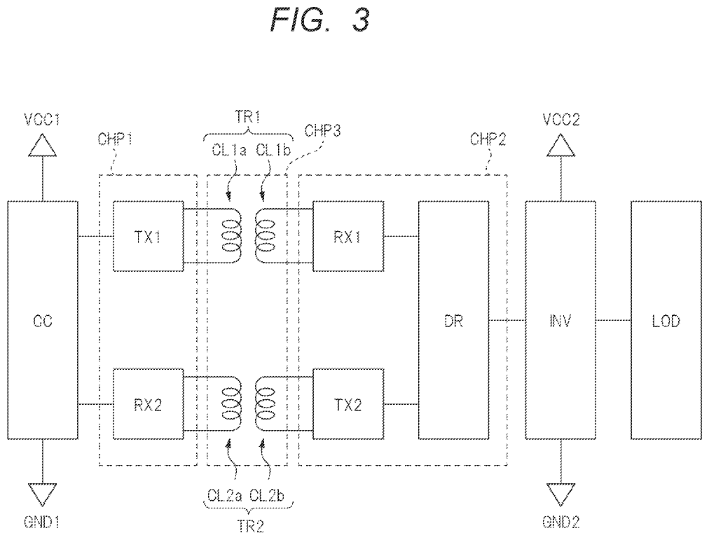

FIG. 3 is a diagram showing a three-chip configuration.

In FIG. 3, the transmitting circuit TX1 and the receiving circuit RX2 are formed in a semiconductor chip CHP1. In addition, the drive circuit DR, the receiving circuit RX1, and the transmitting circuit TX2 are formed in a semiconductor chip CHP2. On the other hand, the transformer TR1 and the transformer TR2 are formed in a semiconductor chip CHP3.

Thus, in the three-chip configuration, the semiconductor chip CHP3 includes the transformer TR1 and the transformer TR2. That is, in the three-chip configuration, the semiconductor chip CHP3 can be used regardless of the configuration of the semiconductor chip CHP1 and the semiconductor chip CHP2. Thus, according to the three-chip configuration, the usable variation of the semiconductor chip CHP1 and the semiconductor chip CHP2 can be increased. In other words, the versatility of the semiconductor chip CHP3 in which the transformer TR1 and the transformer TR2 are formed can be improved.

Further, since the semiconductor chip CHP3 in which the transformer TR1 and the transformer TR2 are formed does not include a transistor, there is no need to perform a manufacturing step for forming the transistor, and thus the manufacturing step can be simplified. Therefore, according to the three-chip configuration, the manufacturing cost of semiconductor device can be reduced.

### Basic Concept of Embodiment

Next, the basic concept in the present embodiment is explained.

In the basic concept of the present embodiment, a conductive pattern is formed in at least one layer of the multilayer wiring layer in order to improve the pattern occupancy ratio of the “trans-chip”. Thus, according to the basic concept, the pattern occupancy ratio can be improved by the conductive pattern, so that the warp of the semiconductor wafer can be suppressed. As a result, handling of the semiconductor wafer can be facilitated.

Further, according to the basic concept, in the etching for forming the pattern, the etching area is reduced, so that the generation of etching residues can be reduced. Thus, according to the basic concept, generation of foreign matters caused by the residue can be suppressed, and the manufacture yield of semiconductor device can be improved.

Further, in the basic concept, on the assumption that a conductive pattern is formed in at least one layer of the multilayer wiring layer, the conductive pattern is formed so as to continuously surround the lower inductor and the upper inductor in plan view. According to the basic concept, the conductive pattern functions as a “beam” for reinforcing the multilayer wiring layer.

That is, the basic concept has not only the technical significance of improving the pattern occupancy ratio by forming a conductive pattern in at least one layer of the multilayer wiring layer, but also the technical significance of causing the conductive pattern to function as a “beam” for reinforcing the structure of the multilayer wiring layer. That is, the basic concept has not only the technical significance of suppressing the warp of the semiconductor wafer by increasing the pattern occupancy ratio, but also the technical significance of preventing the multilayer wiring layer from being broken even if the warp occurs in the semiconductor wafer. Thus, according to the basic concept, the reliability of the “trans-chip” included in the semiconductor device can be improved.

Here, the multilayer wiring layer includes a wiring layer and a plug layer. The wiring layer includes a wiring and an interlayer dielectric film. On the other hand, the plug layer includes a plug and an interlayer dielectric film.

Note that wiring layer and the plug layer may be formed not only separately but also integrally.

In addition, in the present specification, “forming a conductive pattern so as to continuously surround the lower inductor and the upper inductor in plan view” does not assume that the lower inductor, the upper inductor, and the conductive pattern are present in the same plane.

That is, for example, assuming a configuration in which the lower inductor is present in a first plane corresponding to the first wiring layer and the upper inductor is present in a second plane corresponding to the second wiring layer, this term means not only a configuration in which the conductive pattern is present in either the first plane or the second plane, but also a configuration in which the conductive pattern is present in a third plane corresponding to a third wiring layer that differs from the first wiring layer and the second wiring layer.

For example, when attention is paid to the third plane, the sentence “forming a conductive pattern so as to continuously surround the lower inductor and the upper inductor in plan view” includes the meaning that “a dielectric film (interlayer dielectric film) is formed between the lower inductor and the upper inductor, and the conductive pattern continuously surrounds a portion of the dielectric film that overlaps the lower inductor and the upper inductor in plan view”.

In the following, an embodiment embodying the basic concept will be described.

### EMBODIMENT

### Configuration of Semiconductor Device

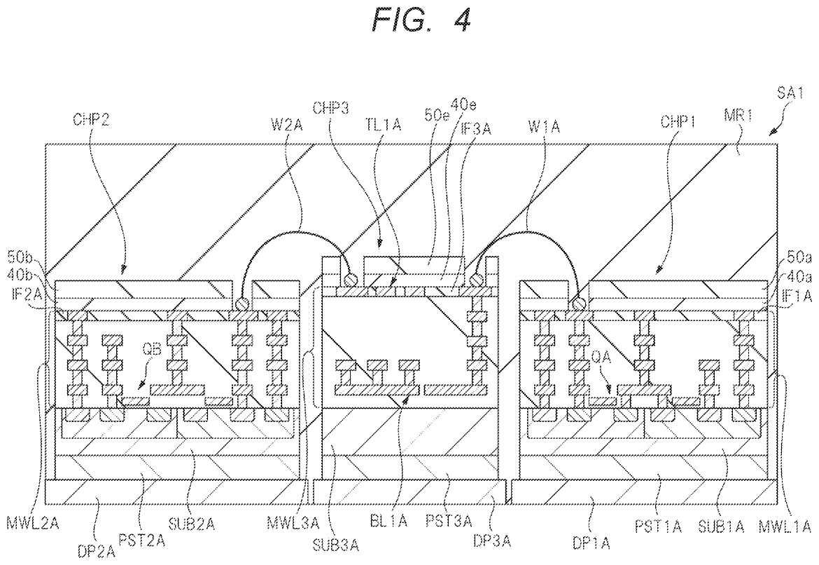

FIG. 4 is a cross-sectional view showing a configuration of a semiconductor device SA1 in the embodiment.

In FIG. 4, the semiconductor device SA1 includes the semiconductor chip CHP1, the semiconductor chip CHP2, and the semiconductor chip CHP3. That is, the semiconductor device SA1 in the embodiment shown in FIG. 4 has a three-chip configuration.

The semiconductor chip CHP1 is mounted, for example, on a die pad DP1A via a conductive adhesive PST1A. On the other hand, the semiconductor chip CHP2 is mounted, for example, on a die pad DP2A via a conductive adhesive PST2A. Further, the semiconductor chip CHP3 is mounted on, for example, a die pad DP3A via a conductive adhesive PST3A.

Here, the die pad DP1A, the die pad DP2A, and the die pad DP3A are made of, for example, copper material. The conductive adhesive PST1A, the conductive adhesive PST2A, and the conductive adhesive PST3A are made of, for example, silver-paste or solder.

The transmitting circuit TX1 and the receiving circuit RX2 shown in FIG. 3 are formed in the semiconductor chip CHP1. As shown in FIG. 4, the semiconductor chip CHP1 includes a semiconductor substrate SUB1A and a multilayer wiring layer MWL1A formed on the semiconductor substrate SUB1A.

A plurality of transistors QA are formed on the semiconductor substrate SUB1A. The multilayer wiring layer MWL1A is formed over the semiconductor substrate SUB1A on which the plurality of transistors QA are formed. The multilayer wiring layer MWL1A includes a plurality of wiring layers and a plurality of plug layers, and a plug layer is interposed between the wiring layer and the wiring layer. The wiring is formed in each wiring layer of the multilayer wiring layer MWL1A. The wiring is electrically connected to the transistor QA. The transistor QA and the wiring electrically connected to each other configure the transmitting circuit TX1A and the receiving circuit RX2A.

Subsequently, as shown in FIG. 4, in the semiconductor chip CHP1, a wiring and a dielectric film IF1A are formed in the uppermost layer of the multilayer wiring layer MWL1A. The wiring formed in the uppermost layer of the multilayer wiring layer MWL1A includes a pad. On the wiring formed in the uppermost layer of the multilayer wiring layer MWL1A and on the dielectric film IF1A, an inorganic dielectric film 40a is formed. An organic dielectric film 50a is formed on the inorganic dielectric film 40a. Here, the inorganic dielectric film 40a is formed of a silicon nitride film. On the other hand, the organic dielectric film 50a is formed of a polyimide resin film.

Next, the transmitting circuit TX2, the receiving circuit RX1, and the drive circuit DR shown in FIG. 3 are formed in the semiconductor chip CHP2.

As shown in FIG. 4, the semiconductor chip CHP2 includes a semiconductor substrate SUB2A and a multilayer wiring layer MWL2A formed on the semiconductor substrate SUB2A.

A plurality of transistors QB are formed in the semiconductor substrate SUB2A. The multilayer wiring layer MWL2A is formed over the semiconductor substrate SUB2A on which the plurality of transistors QB are formed. The multilayer wiring layer MWL2A includes a plurality of wiring layers and a plurality of plug layers, and a plug layer is interposed between the wiring layer and the wiring layer. The wiring is formed in each wiring layer of the multilayer wiring layer MWL2A. The wiring is electrically connected to the transistor QB. The transistor QB and the wiring electrically connected to each other configure the transmitting circuit TX2A, the receiving circuit RX1A, and the drive circuit DR.

Subsequently, as shown in FIG. 4, in the semiconductor chip CHP2, a wiring and a dielectric film IF2A are formed in the uppermost layer of the multilayer wiring layer MWL2A. The wiring formed in the uppermost layer of the multilayer wiring layer MWL2A includes a pad. On the wiring formed in the uppermost layer of the multilayer wiring layer MWL2A and on the dielectric film IF2A, an inorganic dielectric film 40b is formed. An organic dielectric film 50b is formed on the inorganic dielectric film 40b. Here, the inorganic dielectric film 40b is formed of a silicon nitride film. On the other hand, the organic dielectric film 50b is formed of a polyimide resin film.

Next, the transformer TR1 and the transformer TR2 shown in FIG. 3 are formed in the semiconductor chip CHP3 (“trans-chip”). As shown in FIG. 4, the semiconductor chip CHP3 includes a semiconductor substrate SUB3A and a multilayer wiring layer MWL3A formed on the semiconductor substrate SUB3A. The lowermost layer of the multilayer wiring layer MWL3A is in contact with the semiconductor substrate SUB3A. In addition to wiring, the multilayer wiring layer MWL3A includes a lower inductor BL1A that is a component of the transformer TR1. The lower inductor BL1A is made of, for example, a spiral wiring.

As shown in FIG. 4, in the semiconductor chip CHP3, a wiring and a dielectric film IF3A are formed in the uppermost layer of the multilayer wiring layer MWL3A. Further, an upper inductor TL1A that is a component of the transformer TR1 is formed in the uppermost layer of the multilayer wiring layer MWL3A.

Further, the wiring formed in the uppermost layer of the multilayer wiring layer MWL3A includes a pad. On the wiring formed in the uppermost layer of the multilayer wiring layer MWL3A, on the upper inductor TL1A and on the dielectric film IF3A, an inorganic dielectric film 40e is formed. An organic dielectric film 50e is formed on the inorganic dielectric film 40e. Here, the inorganic dielectric film 40e is formed of a silicon nitride film. On the other hand, the organic dielectric film 50e is formed of a polyimide resin film.

As shown in FIG. 4, the semiconductor chip CHP3 is formed with the upper inductor TL1A and the lower inductor BL1A, which are components of a transformer for performing non-contact communication between different potentials. In this case, the upper inductor TL1A is electrically connected to the wiring in the multilayer wiring layer MWL2A formed in the semiconductor chip CHP2. A second potential, which is a reference potential of about 800 V, is applied to the upper inductor TL1A. Specifically, the semiconductor device SA1 in the embodiment includes the semiconductor chip CHP2 having a circuit (second circuit unit) applying a second potential to the upper inductor TL1A. The upper inductor TL1A formed in the semiconductor chip CHP3 is electrically connected to the circuit formed in the semiconductor chip CHP2 via a bonding wire W2A which is an exemplary conductive member. Accordingly, the second potential outputted from the circuit formed in the semiconductor chip CHP2 is applied to the upper inductor TL1A.

The lower inductor BL1A is electrically connected to the wiring in the multilayer wiring layer MWL1A formed in the semiconductor chip CHP1. The first potential, which is a reference potential of about 0 V, is applied to the lower inductor BL1A. Specifically, the semiconductor device SA1 in the embodiment includes the semiconductor chip CHP1 having a circuit (first circuit unit) that applies a first potential to the lower inductor BL1A. The lower inductor BL1A formed in the semiconductor chip CHP3 is electrically connected to the circuit formed in the semiconductor chip CHP1 via a bonding wire W1A which is an exemplary conductive member. Accordingly, the first potential outputted from the circuit formed in the semiconductor chip CHP1 is applied to the lower inductor BL1A.

As described above, the semiconductor device SA1 includes the semiconductor chip CHP1, the semiconductor chip CHP2, and the semiconductor chip CHP3. In this case, the first circuit unit is formed in the semiconductor chip CHP1. The second circuit unit is formed in the semiconductor chip CHP2. The transformer TR1 is formed in the semiconductor chip CHP3.

The upper inductor TL1A is formed so as to be magnetically coupled to the lower inductor BL1A to which a first potential differing from the second potential is applied in a direction from the semiconductor substrate SUB3A toward the organic dielectric film 50e. Specifically, the upper inductor TL1A is formed in the uppermost layer of the multilayer wiring layer MWL3A, while the lower inductor BL1A is formed in the multilayer wiring layer MWL3A. Thus, the upper inductor TL1A and the lower inductor BL1A are configured to be magnetically coupleable.

As shown in FIG. 4, the semiconductor chip CHP1, the semiconductor chip CHP2, and the semiconductor chip CHP3 configured as described above are sealed with, for example, a mold resin MR1 made of an epoxy resin. In other words, the semiconductor chip CHP1, the semiconductor chip CHP2, and the semiconductor chip CHP3 are covered with the mold resin MR1. In this way, the semiconductor device SA1 having three-chip configuration is configured.

### Plane Configuration of Semiconductor Chip CHP3

Next, the plane configuration of the semiconductor chip CHP3 is explained.

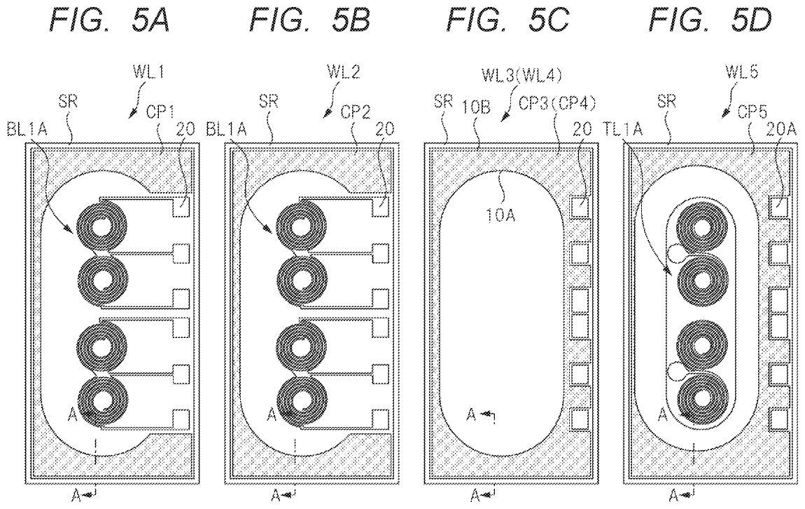

In particular, FIG. 5A is a plan view showing a first wiring layer. FIG. 5B is a plan view showing a second wiring layer disposed over the first wiring layer.

FIG. 5C is a plan view showing each of the third wiring layer disposed over the second wiring layer and the fourth wiring layer disposed over the third wiring layer, and FIG. 5D is a plan view showing the fifth wiring layer disposed over the fourth wiring layer.

### 1. Plane Layout of First Wiring Layer WL1

First, the plane layout of a first wiring layer WL1 of the multilayer wiring layer will be described.

In FIG. 5A, the lower inductor BL1A is formed in the first wiring layer WL1. The lower inductor BL1A is electrically connected to a lead wiring 20. In FIG. 5A, a sealing ring SR is formed so as to continuously surround the lower inductor BL1A. In this embodiment, a conductive pattern CP1 is formed between the sealing ring SR and the lower inductor BL1A. The conductive pattern CP1 is not connected to the sealing ring SR and is spaced apart from the sealing ring SR.

### 2. Plane Layout of Second Wiring Layer WL2

Next, a plane layout of a second wiring layer WL2 of the multilayer wiring layer will be described.

In FIG. 5B, the second wiring layer WL2 is formed with the lower inductor BL1A. The lower inductor BL1A is electrically connected to the lead wiring 20. In FIG. 5B, the sealing ring SR is formed so as to continuously surround the lower inductor BL1A. In this embodiment, a conductive pattern CP2 is formed between the sealing ring SR and the lower inductor BL1A. The conductive pattern CP2 is not connected to the sealing ring SR and is spaced apart from the sealing ring SR.

As described above, the lower inductor BL1A is formed in the first wiring layer WL1 and the second wiring layer WL2. The lower inductor BL1A formed in the first wiring layer WL1 and the lower inductor BL1A formed in the second wiring layer WL2 are connected to each other.

### 3. Plane Layout of Third Wiring Layer WL3 and Fourth Wiring Layer WL4

Next, the plane layout of a third wiring layer WL3 and a fourth wiring layer WL4 of the multilayer wiring layer is explained. In the following, the plane layout of the third wiring layer WL3 will be described. Here, the plane layout of the third wiring layer WL3 and the plane layout of the fourth wiring layer WL4 are similar to each other, and therefore, explanation of the plane layout of the fourth wiring layer WL4 is omitted.

In FIG. 5C, the third wiring layer WL3 is formed with a conductive pattern CP3 and the sealing ring SR. In this case, the conductive pattern CP3 has a first border line 10A and a second border line 10B. The second border line 10B continuously surrounds the first border line 10A. The conductive pattern CP3 is configured by a conductive film surrounded by the first border line 10A and the second border line 10B. In this case, at least the first border line 10A includes a curved line.

Further, in the third wiring layer WL3, the sealing ring SR is formed so as to continuously surround the second border line 10B. The conductive pattern CP3 is not connected to the sealing ring SR and is spaced apart from the sealing ring SR. The lead wiring 20 is formed between the second border line 10B and the sealing ring SR.

### 4. Plane Layout of Fifth Wiring Layer WL5

Next, the plane layout of a fifth wiring layer WL5 of the multilayer wiring layer will be described.

In FIG. 5D, the upper inductor TL1A is formed in the fifth wiring layer WL5. In FIG. 5D, a conductive pattern CP5 is formed so as to continuously surround the upper inductor TL1A. Further, the sealing ring SR is formed so as to continuously surround the conductive pattern CP5. The conductive pattern CP5 is not connected to the sealing ring SR and is spaced apart from the sealing ring SR.

A lead pad 20A electrically connected to the lead wiring 20A is formed between the conductive pattern CP5 and the sealing ring SR.

The semiconductor device includes a “trans-chip” in which a transistor is not formed. Here, the “trans-chip” includes a semiconductor substrate and a multilayer wiring layer formed on the semiconductor substrate and having at least a first layer and a second layer disposed over the first layer. Further, the “trans-chip” includes a lower inductor formed in the first layer of the multilayer wiring layer, an upper inductor formed in the second layer of the multilayer wiring layer and overlapping the lower inductor in plan view, and a conductive pattern formed in at least one layer of the multilayer wiring layer. The at least one layer of the multilayer wiring layer includes the first layer, the second layer, and a layer formed between the first layer and the second layer. In this case, the conductive pattern continuously surrounds the lower inductor and the upper inductor in plan view.

Here, for example, when attention is paid to the third wiring layer WL3 shown in FIG. 5C, the sentence “forming a conductive pattern so as to continuously surround the lower inductor BL1A and the upper inductor TL1A in plan view” also includes the meaning that “a dielectric film (interlayer dielectric film) is formed between the lower inductor BL1A and the upper inductor TL1A, and the conductive pattern CP3 continuously surrounds a portion of the dielectric film that overlaps the lower inductor BL1A and the upper inductor TL1A in plan view.”

The semiconductor chip CHP3 is configured as described above.

### Cross-Sectional Configuration of Semiconductor Chip CHP3

Subsequently, the cross-sectional configuration of the semiconductor chip CHP3 is explained.

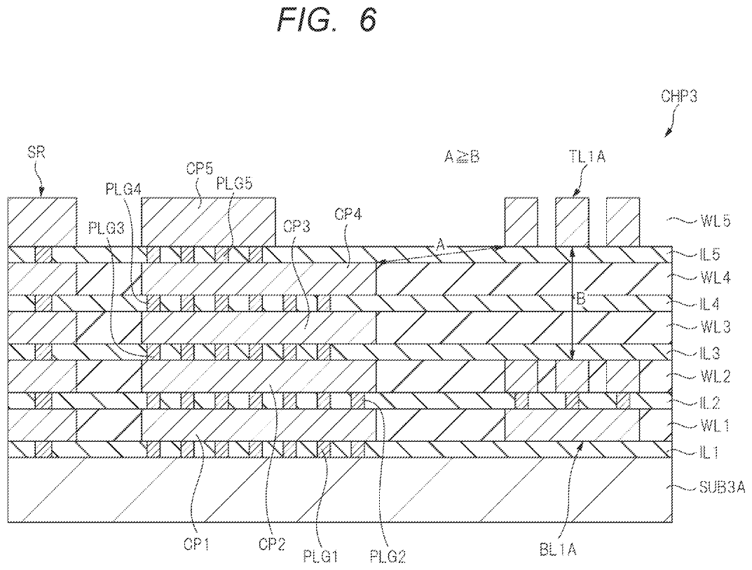

FIG. 6 is a cross-sectional view along A-A line of FIG. 5.

In FIG. 6, the multilayer wiring layer is formed on the semiconductor substrate SUB3A. Specifically, the first wiring layer WL1 is formed on the semiconductor substrate SUB3A via an interlayer dielectric film IL1 configuring the plug layer. The second wiring layer WL2 is formed on the first wiring layer WL1 via an interlayer dielectric film IL2 configuring the plug layer. The third wiring layer WL3 is formed on the second wiring layer WL2 via an interlayer dielectric film IL3 configuring the plug layer. The fourth wiring layer WL4 is formed on the fourth wiring layer WL3 via an interlayer dielectric film IL4 configuring the plug layer. Further, the fifth wiring layer WL5 is formed on the fourth wiring layer WL4 via an interlayer dielectric film IL5 configuring the plug layer.

As shown in FIG. 6, the sealing ring SR is formed in the multilayer wiring layer. On the other hand, the lower inductor BL1A is formed over the first wiring layer WL1 and the second wiring layer WL2. The lower inductor formed in the first wiring layer WL1 and the lower inductor formed in the second wiring layer WL2 are electrically connected to each other by a plurality of plugs penetrating through the interlayer dielectric film IL2. Thus, the lower inductor BL1A is formed over the first wiring layer WL1 and the second wiring layer WL2. The upper inductor TL1A that overlaps the lower inductor BL1A in plan view is formed over the lower inductor BL1A. Specifically, the upper inductor TL1A is formed in the fifth wiring layer WL5 formed on the interlayer dielectric film IL5.

Next, as shown in FIG. 6, a conductive pattern is formed between the sealing ring SR and the transformer formed of the upper inductor TL1A and the lower inductor BL1A. Specifically, the conductive pattern includes the conductive pattern CP1 formed in the first wiring layer WL1, the conductive pattern CP2 formed in the second wiring layer WL2, the conductive pattern CP3 formed in the third wiring layer WL3, a conductive pattern CP4 formed in the fourth wiring layer WL4, and the conductive pattern CP5 formed in the fifth wiring layer WL5.

Here, the conductive pattern CP1 is electrically connected to the semiconductor substrate SUB via a plurality of plugs PLG1 configuring the plug layer. The conductive pattern CP1 and the conductive pattern CP2 are electrically connected to each other via a plurality of plugs PLG2 configuring the plug layer. Further, the conductive pattern CP2 and the conductive pattern CP3 are electrically connected to each other via a plurality of plugs PLG3 configuring the plug layer.

Similarly, the conductive pattern CP3 and the conductive pattern CP4 are electrically connected to each other via a plurality of plugs PLG4 configuring the plug layer. The conductive pattern CP4 and the conductive pattern CP5 are electrically connected to each other via a plurality of plugs PLG5 configuring the plug layer.

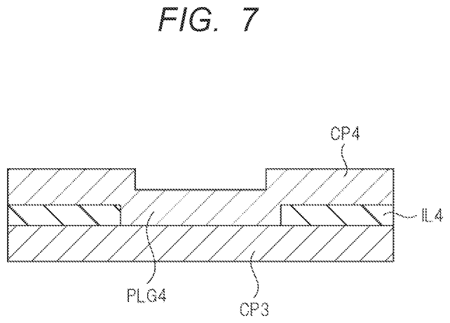

For example, a plug electrically connecting the upper and lower conductive patterns can be formed by burying a tungsten film in a via hole. As shown in FIG. 7, the conductive pattern CP4 may be formed over the conductive pattern CP3, and the conductive pattern CP4 and the plurality of plugs PLG4 may be formed of the same film. That is, as shown in FIG. 7, the conductive pattern CP4 may be formed by burying an aluminum film configuring the conductive pattern CP4 in the via hole by increasing the width of the via hole in which the plug PLG4 is formed.

Subsequently, in FIG. 6, the shortest distance A between the conductive pattern and the upper inductor TL1A is equal to or greater than a distance B between the lower inductor BL1A and the upper inductor TL1A. Further, as shown in FIG. 6, the interlayer dielectric film in contact with the conductive pattern is formed over or under the conductive pattern, and a thickness of the conductive pattern is equal to or greater than a thickness of the interlayer dielectric film. For example, in FIG. 6, the interlayer dielectric film IL4 in contact with the conductive pattern CP3 is formed over the conductive pattern CP3, and a thickness of the conductive pattern CP3 is equal to or greater than a thickness of the interlayer dielectric film IL4. Similarly, the interlayer dielectric film IL3 in contact with the conductive pattern CP3 is formed under the conductive pattern CP3, and a thickness of the conductive pattern CP3 is equal to or greater than a thickness of the interlayer dielectric film IL3.

The semiconductor chip CHP3 is configured as described above.

### Features in Embodiment

Next, the features in the embodiment will be described.

A first feature of the embodiment is that at least one layer of the multilayer wiring layer formed in the “trans-chip” is formed with a conductive pattern surrounded by a sealing ring. Thus, according to the first feature, since the pattern occupancy ratio in the “trans-chip” can be improved by the conductive pattern, it is possible to suppress the warp of the semiconductor wafer. As a result, according to the first feature, handling of the semiconductor wafer can be facilitated. Further, according to the first feature, since the etching area can be reduced in the etching for forming the pattern, the generation of the etching residue can be reduced. Thus, according to the first feature, generation of foreign matter caused by the residue can be suppressed, and the manufacture yield of the semiconductor device can be improved.

Further, in the first feature, on the assumption that a conductive pattern is formed in at least one layer of the multilayer wiring layer, the conductive pattern is formed so as to continuously surround the lower inductor and the upper inductor in plan view. Thus, according to the first feature, the conductive pattern is formed so as to continuously surround the lower inductor and the upper inductor in plan view, and the conductive pattern functions as a “beam” that reinforces the structure of the multilayer wiring layer.

That is, the first feature has not only the technical significance of improving the pattern occupancy ratio by forming the conductive pattern in at least one layer of the multilayer wiring layer, but also the technical significance of causing the conductive pattern to function as a “beam” for reinforcing the structure of the multilayer wiring layer. In other words, the first feature not only has the technical significance of suppressing the warp of the semiconductor wafer by increasing the pattern occupancy ratio, but also has the technical significance of preventing the multilayer wiring layer from being broken even if the warp occurs in the semiconductor wafer. Consequently, according to the first feature, the reliability of the “trans-chip” included in the semiconductor device can be improved.

In particular, in the first feature, in order to make the conductive pattern function as a “beam” that reinforces a structure formed of a multilayer wiring layer, it is necessary to form the conductive pattern so as to continuously surround the lower inductor and the upper inductor in plan view. That is, configuring the conductive pattern from the “closed pattern” is necessary for causing the conductive pattern to function as a “beam”. This is because, when stress is applied to the conductive pattern, the “closed pattern” is less likely to be deformed than the “open pattern”. That is, by configuring the conductive pattern from the “closed pattern”, it is possible that the conductive pattern is less likely to be deformed by stress. This means that the conductive pattern can be sufficiently functioned as a “beam” for reinforcing the multilayer wiring layer by forming the conductive pattern from a “closed pattern”. Therefore, the first feature has not only the technical significance of suppressing the occurrence of warp by increasing the pattern occupancy ratio, but also the technical significance of forming a structure capable of withstanding the stress caused by the warp even if the warp occurs.

Subsequently, a second feature of the embodiment is that a plurality of conductive patterns is connected by a plurality of plugs on the assumption that conductive pattern is formed in each of two or more wiring layers of the multilayer wiring layer. For example, when the first conductive pattern is formed in the first wiring layer and the second conductive pattern is formed in the second wiring layer disposed over the first wiring layer, the first conductive pattern and the second conductive pattern are connected to each other by a plurality of plugs penetrating through the interlayer dielectric film formed between the first wiring layer and the second wiring layer.

Thus, according to the second feature, since the plurality of conductive patterns are formed in the plurality of layers, it is possible to further increase the pattern occupancy ratio in the “trans-chip”. In addition, since a plurality of conductive patterns are present, the number of conductive patterns that function as “beams” for reinforcing the multilayer wiring layer can be increased. As a result, the structure formed of the multilayer wiring layer is less likely to be broken by the warp. Further, according to the second feature, since the conductive patterns formed in the different layers are connected to each other by the plurality of plugs, the plurality of plugs function as “pillars” that reinforce the multilayer wiring layer. Consequently, according to the second feature, since the “beam” and the “pillar” are formed to reinforce the structure formed of the multilayer wiring layer, it is possible to provide a structure capable of withstanding the stresses caused by the warp even if the warp occurs.

Further, according to the second feature, since the plurality of plugs are formed in the interlayer dielectric film, the volume of the interlayer dielectric film is reduced, and as a result, the warp of the semiconductor wafer caused by the interlayer dielectric film can be suppressed. In particular, in order to reduce the volume of the interlayer dielectric film and suppress the warp of the semiconductor wafer caused by the interlayer dielectric film, it is desirable to increase the number of plugs and increase the width of the plugs (see FIG. 7).

From the above, the second feature has not only the technical significance of improving the pattern occupancy ratio, but also the technical significance of causing each of the plugs to function as a “pillar” for reinforcing the structure of the multilayer wiring layer.

Next, as shown in FIG. 6, a third feature of the embodiment is that the thickness of the conductive pattern is equal to or greater than the thickness of the interlayer dielectric film. That is, on the premise that the interlayer dielectric film in contact with the conductive pattern is formed over or under the conductive pattern, the thickness of the conductive pattern is equal to or greater than the thickness of the interlayer dielectric film.

As a result, the volume of the conductive pattern that generates the stress opposite to the stress of the interlayer dielectric film increases, and therefore, the stress caused by the interlayer dielectric film is reduced by the opposite stress. As a result, the warp of the semiconductor wafer caused by the stress generated based on the interlayer dielectric film can be suppressed.

Subsequently, a fourth feature of the embodiment is that an inner peripheral border line of the conductive pattern formed of the conductive film surrounded by the inner peripheral border line and the outer peripheral border line in plan view includes a curved line. Specifically, for example, in FIG. 5C, the first border line 10A is configured to include a curved line on the premise that the conductive pattern CP3 is formed of the conductive film surrounded by the first border line 10A and the second border line 10B that continuously surrounds the first border line 10A in plan view.

As a result, it is possible to prevent the corner portion that causes the breakdown voltage to be lowered from being formed in the first border line 10A that continuously surrounds the upper inductor TL1A and the lower inductor BL1A in plan view. As a result, according to the fourth feature, the breakdown voltage of the “trans-chip” can be improved. On the other hand, the second border line 10B, which is the outer peripheral border line, is highly flexible in designing the second border line 10B without restrictions such as the first border line 10A. Thus, for example, as shown in FIG. 5C, a cutout portion can be formed in the second border line 10B to secure an area in which the lead wiring 20 is disposed.

Next, as shown in FIG. 6, the fifth feature of the embodiment is that the shortest distance between the conductive pattern and the upper inductor (the distance between the conductive pattern CP4 and the upper inductor TL1A in FIG. 6) is equal to or greater than the distance between the lower inductor BL1A and the upper inductor TL1A. Accordingly, the breakdown voltage of the “trans-chip” can be secured.

For example, the breakdown voltage of the transformer formed in the “trans-chip” is determined by appropriately designing the distance B between the lower inductor BL1A and the upper inductor TL1A. Therefore, when the shortest distance A between the conductive pattern and the upper inductor TL1A is smaller than the above-described distance B, even if the distance B is designed so as to secure the breakdown voltage of the transformer, it is difficult to secure the breakdown voltage as designed by the presence of the shortest distance A smaller than the distance B.

In this regard, according to the fifth aspect, the shortest distance A may be greater than or equal to the distance B. In this case, since the shortest distance A is equal to or greater than the distance B, it is possible to avoid the breakdown voltage of the formed transformer being lower than the breakdown voltage designed based on the distance B. As described above, according to the fifth feature, even if a new conductive pattern is added to the “trans-chip”, the breakdown voltage determined by appropriately designing the distance B between the lower inductor BL1A and the upper inductor TL1A can be secured.

The invention made by the present inventor has been described above in detail based on the embodiment, but the present invention is not limited to the embodiment described above, and it is needless to say that various modifications can be made without departing from the gist thereof.

What is claimed is:

1. A semiconductor device comprising:
a first semiconductor chip in which a transistor is not formed,
wherein the first semiconductor chip comprising:
a semiconductor substrate;
a multilayer wiring layer formed on the semiconductor substrate, the multilayer wiring layer comprising:
a first layer; and
a second layer disposed over the first layer;
a lower inductor formed in the first layer of the multilayer wiring layer;
an upper inductor formed in the second layer of the multilayer wiring layer, the upper inductor overlapping the lower inductor in plan view; and
a conductive pattern formed in at least one layer of the multilayer wiring layer,
wherein the conductive pattern continuously surrounds the lower inductor and the upper inductor in plan view.

2. The semiconductor device according to claim 1,
wherein the conductive pattern comprising:
a first conductive pattern formed in one layer of the multilayer wiring layer; and
a second conductive pattern formed in an another layer of the multilayer wiring layer.

3. The semiconductor device according to claim 2,
wherein the first conductive pattern and the second conductive pattern are connected to each other via a plurality of plugs.

4. The semiconductor device according to claim 3,
wherein the second conductive pattern is formed over the first conductive pattern, and
wherein the second conductive pattern and the plurality of plugs are configured by the same film.

5. The semiconductor device according to claim 1,
wherein the first semiconductor chip comprises a sealing ring continuously surrounding the conductive pattern in plan view.

6. The semiconductor device according to claim 1,
wherein the conductive pattern is configured by a conductive film, the conductive film is surrounded by a first border line continuously surrounding the lower inductor and the upper inductor in plan view and a second border line continuously surrounding the first border line in plan view, and
wherein the first border line has a curved line.

7. The semiconductor device according to claim 1,
wherein the conductive pattern has a function of suppressing a warp of the semiconductor substrate.

8. The semiconductor device according to claim 3,
wherein each of the plurality of plugs has a function of suppressing a warp of the semiconductor substrate.

9. The semiconductor device according to claim 1,
wherein a shortest distance between the conductive pattern and the upper inductor is equal to or greater than a distance between the lower inductor and the upper inductor.

10. The semiconductor device according to claim 1,
wherein a dielectric film in contact with the conductive pattern is formed over or under the conductive pattern, and
wherein a thickness of the conductive pattern is equal to or greater than a thickness of the dielectric film.

11. The semiconductor device according to claim 1,
wherein a dielectric film is formed between the lower inductor and the upper inductor, and
wherein the conductive pattern continuously surrounds a portion of the dielectric film overlapping the lower inductor and the upper inductor in plan view.

12. The semiconductor device according to claim 1, comprising:
a second semiconductor chip different from the first semiconductor chip,
wherein the second semiconductor chip is electrically connected to the upper inductor or the lower inductor.

13. The semiconductor device according to claim 12,
wherein the second semiconductor chip includes a first transmitting circuit or a first receiving circuit,
wherein a transistor used for the first transmitting circuit or the first receiving circuit is formed in the second semiconductor chip, and
wherein the first transmitting circuit or the first receiving circuit is electrically connected to the upper inductor or the lower inductor.

14. The semiconductor device according to claim 13, comprising:
a third semiconductor chip different from the first semiconductor chip and the second semiconductor chip,
wherein the third semiconductor chip includes a second transmitting circuit or a second receiving circuit,
wherein a transistor used for the second transmitting circuit or the second receiving circuit is formed in the third semiconductor chip,
wherein the first transmitting circuit or the first receiving circuit is electrically connected to one of the upper inductor and the lower inductor, and
wherein the second transmitting circuit or the second receiving circuit is electrically connected to the other of the upper inductor and the lower inductor.
